(19) United States
(12) Patent Application Publication
(10) Pub. No.: US 2024/0282570 A1
(43) Pub. Date: Aug. 22, 2024

(54) RADICAL-ACTIVATED CARBON FILM DEPOSITION

(71) Applicant: Lam Research Corporation, Fremont, CA (US)

(72) Inventors: Bhadri N. VARADARAJAN, Beaverton, OR (US); Matthew Scott WEIMER, Portland, OR (US)

(21) Appl. No.: 18/569,100

(22) PCT Filed: Jun. 16, 2022
(86) PCT No.: PCT/US2022/033777

§ 371 Date: Dec. 11, 2023

Related U.S. Application Data
(60) Provisional application No. 63/202,775, filed on Jun. 23, 2021.

(51) Int. Cl. H01L 21/02; C23C 16/26; C23C 16/50; H01L 21/768

(52) U.S. Cl. CPC H01L 21/02115; C23C 16/26; C23C 16/50; H01L 21/02205; H01L 21/76831

(57) ABSTRACT

Crystalline or amorphous carbon films are deposited on a substrate using radical-activated carbon-containing precursors. The carbon-containing precursors include one or more C—C bonds and/or one or more C—H bonds. Radicals are generated in a remote plasma source located upstream of a reaction chamber, and carbon-containing precursors are flowed into the reaction chamber downstream from the remote plasma source. The radicals interact with the C—C bonds and/or C—H bonds to activate the carbon-containing precursors in an environment adjacent to the substrate. In some implementations, highly conformal amorphous carbon films are deposited by radical-activated carbon-containing precursors.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

Implementations herein relate to deposition of amorphous or crystalline carbon films and, more particularly to indirect plasma-based deposition of amorphous or crystalline carbon films by radical activation of precursor gases.

### BACKGROUND

Carbon films can be obtained with structures ranging from amorphous to nanocrystalline and polycrystalline, ranging from diamond-like to graphitic. Carbon films may have various amounts of sp3 to sp2 bonds. They may also range from pure carbon to having various amounts of hydrogen. Properties of carbon films may be changed depending on deposition methods and process conditions. Many carbon films exhibit excellent properties such as properties related to hardness, resistivity, chemical stability, transparency, etch selectivity, friction, and corrosion-resistance. Thus, carbon films may be useful in a number of thermal, chemical, or mechanical environments. For example, carbon films may be applied in mechanical devices as protective coatings or in electronic devices and semiconductors as hard masks, coatings, or other applications.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of depositing an amorphous or crystalline carbon film on a substrate. The method includes flowing one or more carbon-containing precursors into a reaction chamber toward a substrate in the reaction chamber, each of the carbon-containing precursors having at least one of: one or more C—C bonds or one or more C—H bonds, and generating, from a source gas, radicals of the source gas in a remote plasma source that is positioned upstream of the one or more carbon-containing precursors. The method further includes introducing the radicals of the source gas into the reaction chamber toward the substrate, where the radicals are in an energy state sufficient to activate C—C bonds and/or C—H bonds and form activated carbon radical-containing precursors in an environment adjacent to the substrate, and where the activated carbon radical-containing precursors deposit to form an amorphous or crystalline carbon film on the substrate.

In some implementations, the source gas comprises hydrogen gas and the radicals of the source gas are radicals of hydrogen. In some implementations, the radicals of hydrogen are radicals of hydrogen in a ground state in an environment adjacent to the substrate. In some implementations, the substrate comprises a non-metal layer of silicon oxide, silicon nitride, silicon, or carbon, and the amorphous or crystalline carbon film being deposited on the non-metal layer. In some implementations, the substrate comprises a metal layer of copper, cobalt, molybdenum, tungsten, or ruthenium, and the amorphous or crystalline carbon film being deposited on the metal layer. In some implementations, the one or more carbon-containing precursors comprise at least one of a linear alkene, linear alkyne, branched alkene, branched alkyne, cyclic alkene, or cyclic alkyne group. In some implementations, the one or more carbon-containing precursors comprise a branched alkane group or cyclic alkane group. In some implementations, the one or more carbon-containing precursors comprise a halo-substituted alkane, halo-substituted alkene, or halo-substituted alkyne group. In some implementations, the one or more carbon-containing precursors comprise a haloalkyl-substituted alkane, haloalkyl-substituted alkene, haloalkyl-substituted alkyne, carboxyl-substituted alkane, carboxyl-substituted alkene, carboxyl-substituted alkyne, cyano-substituted alkane, cyano-substituted alkene, cyano-substituted alkyne, carbonyl-substituted alkane, carbonyl-substituted alkene, carbonyl-substituted alkyne, sulfonyl-substituted alkane, sulfonyl-substituted alkene, sulfonyl-substituted alkyne, nitro-substituted alkane, nitro-substituted alkene, nitro-substituted alkyne, sulfonyl halide-substituted alkene, sulfonyl halide-substituted alkene, sulfonyl halide-substituted alkyne, sulfonamide-substituted alkane, sulfonamide-substituted alkene, or sulfonamide-substituted alkyne group. In some implementations, the one or more carbon-containing precursors comprise an alcohol-substituted alkane, alcohol-substituted alkene, alcohol-substituted alkyne, ether-substituted alkane, ether-substituted alkene, ether-substituted alkyne, ether-substituted alkane, ether-substituted alkene, ether-substituted alkyne, O-acyl-substituted alkane, O-acyl-substituted alkene, O-acyl-substituted alkyne, amine-substituted alkane, amine-substituted alkene, amine-substituted alkyne, N-acyl-substituted alkane, N-acyl-substituted alkene, or N-acyl-substituted alkyne group. In some implementations, the amorphous or crystalline carbon film is an amorphous carbon film having a hydrogen content between about 20 atomic % and about 70 atomic %. In some implementations, the substrate has one or more recessed features, the amorphous or crystalline carbon film being deposited in the one or more recessed features and having a step coverage equal to or greater than about 90%. In some implementations, the amorphous carbon film has a refractive index between about 1.5 and about 2.5 and a density between about 1.1 g/cm³ and about 3.5 g/cm³. In some implementations, the amorphous carbon film is deposited at a deposition rate equal to or greater than about 4 Å per minute at a deposition temperature between about 50° C. and about 550° C. in some implementations, an amount of sp3 carbon bonding in the amorphous or crystalline carbon film is equal to or greater than about 25%.

Also provided herein is a method of depositing an amorphous hydrogenated carbon film on a substrate. The method includes flowing one or more carbon-containing precursors into a reaction chamber toward a substrate in the reaction chamber, each of the carbon-containing precursors having at least one of: one or more C—C bonds or one or more C—H bonds, and generating, from a hydrogen source gas, radicals of hydrogen in a remote plasma source that is positioned upstream of the one or more carbon-containing precursors. The method further includes introducing the radicals of hydrogen into the reaction chamber and toward the substrate, where the radicals are in an energy state sufficient to activate the one or more C—C bonds and/or the one or more C—H bonds and form activated carbon-containing precursors in an environment adjacent to the substrate, where the activated carbon-containing precursors deposit to form an amorphous hydrogenated carbon film on the substrate, a hydrogen content between about 20 atomic % and about 70 atomic %.

In some implementations, the amorphous hydrogenated carbon film has a density between about 1.1 g/cm³ and about 3.5 g/cm³. In some implementations, the one or more carbon-containing precursors comprise at least one of a linear alkene, linear alkyne, branched alkene, branched alkyne, cyclic alkene group, or cyclic alkyne group. In some implementations, the one or more carbon-containing precursors comprise a branched alkane group and/or cyclic alkane group. In some implementations, the substrate has one or more recessed features, the amorphous hydrogenated carbon film being deposited in the one or more recessed features and having a step coverage equal to or greater than about 90%.

### BRIEF DESCRIPTION OF THE DRAWINGS

FIG. 1 illustrates a ternary phase diagram of amorphous carbons based on sp2, sp3, and hydrogen content.

FIG. 2 illustrates a flow diagram of an example method of depositing an amorphous or crystalline carbon film according to some implementations.

FIG. 3 illustrates a schematic diagram of an example plasma processing apparatus with a remote plasma source according to some implementations.

FIG. 4A illustrates a cross-sectional schematic of an example carbon film deposited on a dielectric layer of a substrate.

FIG. 4B illustrates a cross-sectional schematic of an example carbon film deposited on a semiconducting layer of a substrate.

FIG. 4C illustrates a cross-sectional schematic of an example carbon film deposited on a metal layer of a substrate.

FIG. 5A illustrates a cross-sectional schematic of an example carbon film as a liner layer deposited in a dual damascene structure.

FIG. 5B illustrates a cross-sectional schematic of an example carbon film as a deposition inhibitor on a substrate.

FIG. 5C illustrates a cross-sectional schematic of an example conformal carbon film as a gapfill in recessed features.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

Carbon is one of the most versatile elements and manifests in a wide variety of allotropic forms that exhibit a diverse range of properties. Amorphous carbons form a big class of carbon allotropes. Amorphous carbons contain a certain degree of disorder or non-crystallinity compared to crystalline structures of diamond and graphite. Amorphous or crystalline carbons may be characterized through the ratio of sp2 to sp3 hybridized bonds in the material. Graphite consists purely of sp2 hybridized bonds and diamond consists purely of sp3 hybridized bonds. Some carbon materials may be stabilized with hydrogen so that the carbon materials are hydrogenated.

The amount of sp2 hybridized bonds, the amount of sp3 hybridized bonds, and the amount of hydrogen content in a carbon film are important factors in determining the properties of the carbon film. Carbon films may be deposited using any number of suitable deposition techniques such as chemical vapor deposition (CVD), plasma-enhanced chemical vapor deposition (PECVD), and physical vapor deposition (PVD) (e.g., sputtering). The ratio of sp2 to sp3 hybridized bonds and the hydrogen content can be controlled depending on deposition technique and deposition parameters. In turn, the properties of a carbon film including its density, hardness, compressive stress, chemical resistance, thermal stability, mechanical properties, and optical properties are impacted.

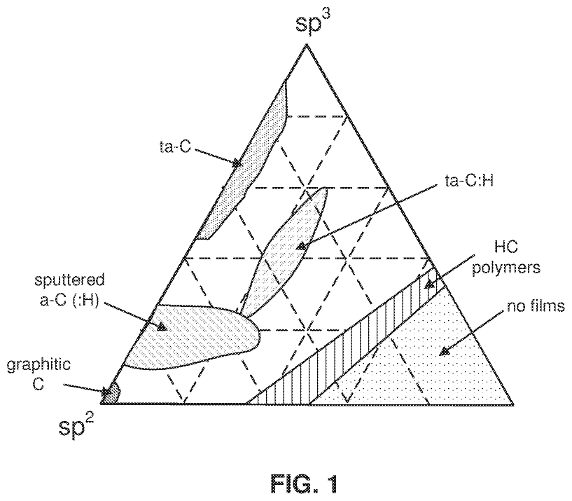

FIG. 1 illustrates a ternary phase diagram of amorphous carbons based on sp2, sp3, and hydrogen content. The ternary phase diagram is used to classify and characterize amorphous or crystalline carbon based on sp2, sp3, and hydrogen content. The three corners correspond to diamond (purely sp3 bonds), graphite (purely sp2 bonds), and hydrogen. Greater amounts of sp3 bonding corresponds to more diamond-like carbon, and greater amounts of sp2 bonding corresponds to more graphitic carbon. Adding hydrogen to the carbon film shifts the carbon film to more polymer-like structures, showing an increasing grade of amorphous phase with increasing hydrogen content. Diamond-like carbon (DLC) films are amorphous carbon films having some or a substantial fraction of sp3 hybridized bonds. The amount of sp3 bonding in DLC typically ranges from about 10% to about 90%. One type of DLC film is tetrahedral amorphous carbon (ta-C), which has mostly sp3 hybridized bonds and little to no hydrogen. Another type of DLC film is tetrahedral amorphous hydrogenated carbon (ta-C:H), which contains more hydrogen than ta-C. Hydrogenated amorphous carbons (a-C:H) generally have less sp3 content than ta-C and ta-C:H. Sputtered amorphous carbon may have more sp2 bonding than sp3 bonding to produce a more graphitic carbon. Where the hydrogen content exceeds greater than about 40 atomic %, the carbon film may be characterized as polymer-like hydrogenated carbon (HC polymers). At a certain point, too much hydrogen content renders carbon film formation impossible so that no film is formed.

The various types of amorphous carbons and their properties can be compared to crystalline carbon (i.e., diamond or graphite) as shown in Table 1. Diamond has a density as high as 3.53 g/cm³ and graphite has a density of about 2.27 g/cm³. Disordered forms of carbon may have different properties than diamond and graphite, particularly as the amount of sp3 bonding or hydrogen content varies. Polymer-like hydrogenated carbon films have a low density of about 1.1 g/cm³. Higher concentrations of hydrogen generally lead to a lower density. Increased sp3 bonding leads to properties that are more diamond-like including properties of increased hardness and increased density.

TABLE 1

| | sp3 (%) | H (atomic %) | Density (g/cm³) | Hardness |
|---|---|---|---|---|
| Diamond | 100 | 0 | 3.53 | 100 |
| Graphite | 0 | 0 | 2.27 | — |
| Evaporated C | 0 | 0 | 1.9 | 3 |
| Sputtered C | 5 | 0 | 2.2 | — |
| ta-C | 80-88 | 0 | 3.1 | 80 |
| a-C:H (hard) | 40 | 30-40 | 1.6-2.2 | 10-20 |
| a-C:H (soft) | 60 | 40-50 | 1.2-1.6 | 10 |
| ta-C:H | 70 | 30 | 2.4 | 50 |

Allotropes of carbon including amorphous carbons are commonly formed using deposition techniques such as thermal CVD and PECVD. Other methods may include electron cyclotron resonance (ECR), plasma-based ion implantation and deposition, and PVD, which includes ionized evaporation, sputtering, magnetron sputtering, filtered cathodic vacuum arc, ion-beam deposition, arc ion plating, pulsed laser deposition, and laser arc deposition. Obtaining high density carbon films having low hydrogen content are typically obtained by either depositing at very high temperatures, e.g., above 600° C., or applying a plasma. Higher temperatures and pressures may be necessary for more sp3 bonding, though such temperatures and pressures may be lowered where plasma is applied. Lower density carbon films having higher hydrogen content may involve lower temperatures and/or plasma at a lower bias voltage. Increasing a concentration of a hydrocarbon-based precursor (e.g., methane) during deposition can also produce lower density carbon films with higher hydrogen content.

Thermal CVD uses elevated temperatures so that hydrocarbon precursors thermally decompose and adsorb onto a substrate surface, where hydrocarbon radicals are chemically reactive to interact with a substrate surface. PECVD uses energized electrons generated by plasma to cause ionization, excitation, and dissociation of hydrocarbon precursors, where ions and radicals of hydrocarbon precursors interact at the substrate surface. A thermal decomposition method such as thermal CVD or a direct plasma method such as PECVD are commonly employed to produce a wide range of amorphous carbon films. Many such amorphous carbon films are covered in the ternary phase diagram shown in FIG. 1 and can be formed by varying deposition process parameters. As a result, various amorphous carbon films of varying sp3 bonding, hydrogen content, hardness, density, refractive index, extinction coefficient, and band gap can be achieved by selecting an appropriate deposition technique and adjusting deposition process parameters. Additionally, crystalline carbon films including diamond and graphite can be formed with the appropriate deposition technique and deposition process parameters.

Amorphous or crystalline carbon films often lack conformality using the aforementioned deposition techniques. Atomic layer deposition (ALD) and plasma-enhanced atomic layer deposition (PEALD) techniques generally have not been established for depositing bulk carbon. In some cases, deposition of certain amorphous or crystalline carbon films may be prohibitive at exceedingly high temperatures. Under high temperatures, various materials such as semiconductors and metals on semiconductor wafers may be physically damaged. In some cases, deposition of amorphous or crystalline carbon films uses plasma with an uncontrolled distribution of plasma-activated species. This leads to more excited radicals and ions acting as depositing species that can densify, sputter, or implant in a growing carbon film. The large distribution of excited radicals and ions in plasma can undesirably affect the conformality, composition, and other properties of the deposited carbon film via the directionality of high energy ions.

The present disclosure deposits carbon films, including amorphous carbon films or amorphous hydrogenated carbon films, using a remote plasma CVD technique. In some cases, crystalline carbon films may be deposited using the remote plasma CVD technique. The remote plasma CVD technique employs radicals such as hydrogen radicals to activate specific bonds in carbon-containing precursors and generate carbon-based radicals in an environment adjacent to a substrate. The carbon-based radicals serve as depositing species for deposition of a carbon film on the substrate. The carbon film deposited by radical-activated carbon-containing precursors avoids the drawbacks associated with thermal decomposition methods and direct plasma methods. Instead of using a direct plasma or in-situ plasma, remote plasma generation of the hydrogen radicals occurs upstream of carbon-containing precursors that are flowed into a reaction chamber holding the substrate. The hydrogen radicals may be in a low energy state such as a ground state in the environment adjacent to the substrate, and the carbon-containing precursors include one or more C—C bonds and/or one or more C—H bonds. In some implementations, the one or more C—C bonds include one or more C═C double bonds or one or more C—C triple bonds. In some implementations, the carbon-containing precursor may further include a functional group such as a halide, haloalkyl, carboxyl, cyano, carbonyl, sulfonyl, nitro, sulfonyl halide, sulfonamide, alcohol, ether, O-acyl, amine, and N-acyl to provide specific bonds in the carbon-containing precursor that may be selectively activated by the hydrogen radicals. In some implementations, the carbon film deposited by the radical-activated carbon-containing precursors may be tuned to a desired hydrogen content such as a hydrogen content between about 20 atomic % and about 70 atomic %. In some implementations, the carbon film deposited by the radical-activated carbon-containing precursors may have an amount of sp3 hybridized bonding equal to or greater than about 25%. In some cases, the carbon film deposited by the radical-activated carbon-containing precursors may have a step coverage equal to or greater than about 90%. The carbon film may be deposited on metal surfaces of a substrate or even non-metal surfaces of the substrate.

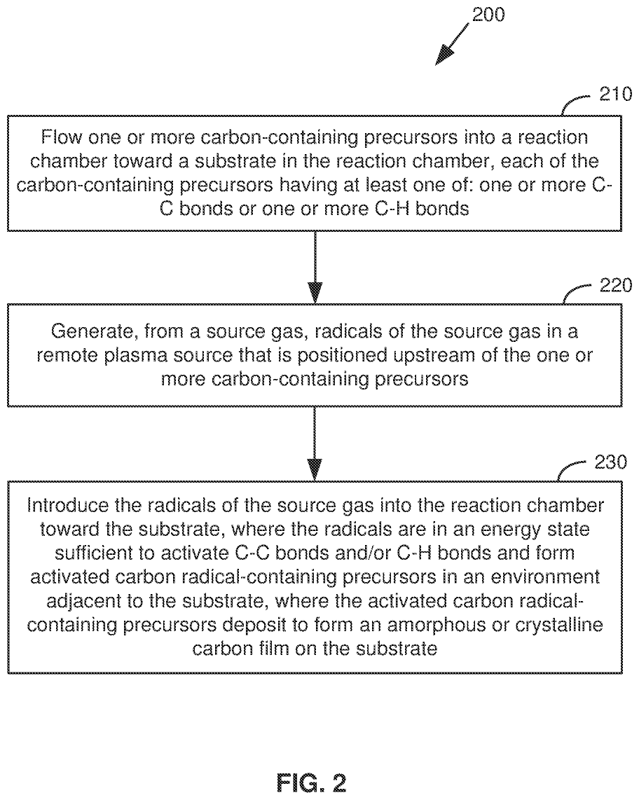

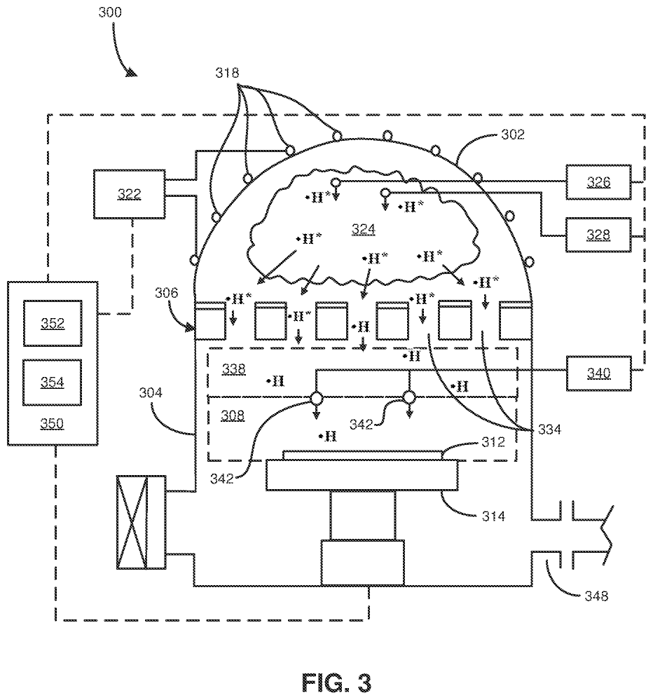

FIG. 2 illustrates a flow diagram of an example method of depositing an amorphous or crystalline carbon film on a substrate according to some implementations. In some embodiments, the example method relates to a method of depositing an amorphous hydrogenated carbon film on a substrate. The operations of a process 200 may be performed in different orders and/or with different, fewer, or additional operations. The operations of the process 200 may be performed using a plasma processing apparatus shown in FIG. 3. In some implementations, the operations of the process 200 may be implemented, at least in part, according to software stored in one or more non-transitory computer readable media.

At block 210 of the process 200, one or more carbon-containing precursors are flowed into a reaction chamber toward a substrate in the reaction chamber, each of the one or more carbon-containing precursors having at least one of: one or more C—C bonds or one or more C—H bonds. However, it will be understood that in some alternative implementations the carbon-containing precursors may include carbon tetrahalides such as carbon tetrachloride (CCl₄), carbon tetrafluoride (CF₄), carbon tetrabromide (CBr₄), and carbon tetraiodide (CI₄), which do not have C—C bonds and/or C—H bonds. The substrate may be supported on a substrate support or pedestal in the reaction chamber. The substrate can be any wafer, semiconductor wafer, partially fabricated integrated circuit, printed circuit board, display screen, or other appropriate workpiece. In some implementations, the substrate may include a metal layer that includes a metal such as copper (Cu), tungsten (W), molybdenum (Mo), cobalt (Co), and ruthenium (Ru). In some implementations, the substrate may include a dielectric layer such as silicon oxide (SiOₓ), silicon nitride (SiₓN_{y}), or amorphous carbon. In some implementations, the substrate may include a semiconducting layer such as silicon (Si). The carbon film may be deposited on the metal layer, dielectric layer, or semiconducting layer. In some implementations, the substrate may include a plurality of substrate features or recessed features, where each of the recessed features may have a high aspect ratio. For instance, the aspect ratio of each of the recessed features may be equal to or greater than about 3:1, equal to or greater than about 5:1, equal to or greater than about 8:1, equal to or greater than about 10:1, or equal to or greater than about 20:1.

Carbon-containing precursors are flowed or otherwise introduced into the reaction chamber via a precursor supply source or precursor gas line. The carbon-containing precursors are supplied into the reaction chamber bypassing any plasma source or plasma-generating region. The carbon-containing precursors enter a space in the reaction chamber that is located downstream from a remote plasma source. The remote plasma source is fluidly coupled to the reaction chamber and located upstream of the reaction chamber. The carbon-containing precursors are flowed to an environment adjacent to the substrate without ionization in a plasma.

The carbon-containing precursors are delivered in the gas phase. The carbon-containing precursors are selected so that radicals generated in the remote plasma source will selectively activate specific bonds in the carbon-containing precursors. Other bonds in the carbon-containing precursors are preserved. In some implementations, the carbon-containing precursors include hydrocarbon precursors. The carbon-containing precursors may have one or more C—C bonds and/or one or more C—H bonds. The C—C bonds may include C—C single bonds, C═C double bonds, or C—C triple bonds. The carbon-containing precursors may also have C—N bonds, C—O single bonds, C—O double bonds, C—OH bonds, or C—X bonds, where X represents a halogen (e.g., F, Cl, Br, or I).

In some instances, the hydrocarbon precursor includes only C and H atoms. The hydrocarbon compound can be CₓH_{y}, wherein x is an integer from 1 to 10 and wherein y is an integer from 2 to 24. Yet other non-limiting hydrocarbons can include methane (CH₄), acetylene (C₂H₂), ethylene (C₂H₄), propylene (C₃H₆), propyne (C₃H₄), propadiene (C₃H₄), allene (C₃H₄), cyclopropene (C₃H₄), cyclopropane (C₃H₆), butane (C₄H₁₀), 1,3-butadiene (C₄H₆), 1,2-butadiene (C₄H₆), cyclobutane (C₄H₈), cyclobutene (C₄H₆), isoprene (C₅H₈), piperylene (C₅H₈), neopentane (C₅H₁₂), isopentane (C₅H₁₂), dimethylbutadiene (C₆H₁₀), 1,5-hexadiene (C₆H₁₀), cyclohexane (C₆H₁₂), cyclohexene (C₆H₁₀), benzene (C₆H₆), toluene (C₇H₈), norbornene (C₇H₁₀), 1,7-octadiene (C₈H₁₄), cyclooctane (C₈H₁₆), cyclononane (C₉H₁₈), cyclodecane (C₁₀H₂₀), and the like. Yet other hydrocarbon compounds include alkenes, alkynes, aromatics, and cyclic hydrocarbons.

Other examples of carbon-containing precursors include an aliphatic compound, such as alkanes, alkenes, and alkynes (e.g., a C₁₋₁₀ alkane, C₂-10 alkene, or C₂₋₁₀ alkyne, including linear, branched, or cyclic forms thereof). In some embodiments, the alkane is branched. In particular embodiments, the alkane includes a formula of CH₃—CR¹R²R³, in which R¹ can be H or optionally substituted alkyl; and each of R² and R³ is, independently, optionally substituted alkyl. Possible substitutions can include any described herein, including electron-withdrawing groups and electron-donating groups (e.g., lone pair donor groups).

In other embodiments, the precursor is a cyclic alkane, such as in a cycloaliphatic. In particular embodiments, the alkane is a cycloalkane. Non-limiting cycloalkanes include a C₃, C₄, or C₈₋₁₀ cycloalkane. In particular embodiments, the cycloalkane is a strained cycloalkane. Thus, in some embodiments, one or more carbon-containing precursors may comprise a branched alkane or cyclic alkane group.

Alkenes or alkynes may be linear, branched, and/or cyclic. In one embodiment, the alkene or alkyne is linear or branched. Such linear and branched alkenes can include one, two, three, four, or more carbon-carbon double bonds. Such linear and branched alkynes can additionally or alternatively include one, two, three, four, or more carbon-carbon triple bonds. Non-limiting precursors can include C₂₋₁₀ alkenes and C₂₋₁₀ alkynes. In other embodiments, the alkene includes a formula of R¹R²C═CR³R⁴, in which each of R¹, R², R³, and R⁴ is, independently, H, optionally substituted alkyl (e.g., substituted C₁₋₈ alkyl), or optionally substituted alkenyl (e.g., substituted C₂₋₈ alkenyl). In yet other embodiments, the alkyne includes a formula of R₁C≡CR² in which each of R¹ and R² is, independently, H, optionally substituted alkyl (e.g., substituted C₁₋₈ alkyl), optionally substituted alkenyl (e.g., substituted C₂₋₈ alkenyl), or optionally substituted alkynyl (e.g., substituted C₂₋₈ alkynyl).

In particular embodiments, the precursor is an alkene having one or more double bonds or an alkyne having one or more triple bonds, in which the alkene or the alkyne can be linear or cyclic. In some embodiments, the precursor comprises a linear alkene, a branched alkene, or cyclic alkene. Example alkenes include ethene, propene, 1-butene, 1-pentene, 1-hexene, 1-heptene, 1-octene, and 1-nonene, as well as dienes of any of these and positional isomers if available, in which the location of the double bond is changed (e.g., a positional isomer of 1-butene could be 2-butene, etc.). In some embodiments, the precursor comprises a linear alkyne, a branched alkyne, or cyclic alkyne. Example alkynes include ethyne, propyne, 1-butyne, 1-pentyne, 1-hexyne, 1-heptyne, 1-octyne, and 1-nonyne, as well as positional isomers if available, in which the location of the triple bond is changed (e.g., a positional isomer of 1-butyne could be 2-butyne, etc.). In some cases, one or more carbon-containing precursors comprise at least one of a linear alkene, linear alkyne, branched alkene, branched alkyne, cyclic alkene, or cyclic alkyne group.

Yet other examples of carbon-containing precursors can include a cycloaliphatic compound (e.g., a C₃-12 cycloalkane, C₃-12 cycloalkene, or C₃-12 cycloalkyne) or an aromatic compound (e.g., benzene, toluene, naphthalene, phenanthrene, as well as other polycyclic forms thereof). The carbon-containing precursor can include saturated bonds (single bonds, e.g., C—C bonds or C—H bonds) and/or unsaturated bonds (double or triple bonds, e.g., C═C, C≡C, or C≡N bonds). In another embodiment, the hydrocarbon compound can be cyclic hydrocarbons (e.g., methylcyclohexane).

In some embodiments, the cyclic alkene or alkyne is an aromatic compound. In one embodiment, the aromatic compound includes benzene substituted with one or more functional groups (e.g., any described herein). In some instances, the hydrocarbon is an unsubstituted benzene, a C₁ alkyl-substituted benzene (e.g., toluene, o-xylene, m-xylene, p-xylene), or a substituted aromatic hydrocarbon (e.g., halo-substituted benzene, amine-substituted benzene, C₂₋₈ alkyl-substituted benzene, or halo- and alkyl-substituted benzene, such as cumene, aniline, N,N-dimethylaniline, etc.).

In other embodiments, the cyclic alkene or cyclic alkyne is a cycloaliphatic compound, as described herein, having one or more carbon-carbon double bonds and/or triple bonds (i.e., C═C and/or C≡C bonds). In other embodiments, the precursor is an unsaturated, cyclic hydrocarbon (e.g., cyclopentene, cyclohexene, cycloheptene, fluorene, etc.).

Various functional groups may substitute the carbon-containing precursor, in which the functional group may act as an electron-withdrawing group or as an electron-donating group (e.g., lone pair donor group). These functional groups may affect the bond strengths in one or more C—C bonds, C—H bonds, C—N bonds, C—O single bonds, C—O double bonds, C—OH bonds, or C—X bonds (where X represents a halogen) so that radicals generated in the remote plasma source may selectively break such bonds to activate the carbon-containing precursors. In some embodiments, the bond strengths of the C—C bonds and/or C—H bonds may be affected by the presence of electron-withdrawing groups (e.g., halo groups or haloaliphatic groups).

The electron-withdrawing group can include one or more halogens. In some implementations, the one or more carbon-containing precursors include a halo-substituted alkane, halo-substituted alkene, or halo-substituted alkyne group. In other embodiments, any of the precursors herein can be substituted with one or more halo groups, one or more haloaliphatic groups, or one or more haloalkyl groups. In one non-limiting example, the precursor is an alkane, an alkene, or an alkyne; and the precursor is substituted with one or more halo, haloaliphatic, or haloalkyl groups.

In particular embodiments, the halogen-substituted precursor is a halocarbon compound, such as a haloalkane, a haloalkene, or a haloaromatic. In yet other embodiments, the halocarbon compound is carbon tetrabromide (CBr₄) or carbon tetrachloride (CCl₄). In other instances, the precursor is a halo-substituted C₁ hydrocarbon (e.g., chloroform, methylene chloride) or a C₂-12 hydrocarbon having one or more halogens.

Yet other electron-withdrawing groups include haloaliphatic, haloheteroaliphatic, heteroaliphatic, halo, haloalkyl (e.g., C₁ haloalkyl, including one, two, or three halo substitutions), perfluoroalkyl, alkoxy, carboxyl, cyano, ester, nitro, nitroalkyl, sulfonamide, sulfonate, sulfonyl, sulfonyl halide, and others. Any precursor herein can be substituted with one or more electron-withdrawing groups.

In some implementations, the one or more carbon-containing precursors include one or more haloalkyl-substituted alkane, haloalkyl-substituted alkene, haloalkyl-substituted alkyne, carboxyl-substituted alkane, carboxyl-substituted alkene, carboxyl-substituted alkyne, cyano-substituted alkane, cyano-substituted alkene, cyano-substituted alkyne, carbonyl-substituted alkane, carbonyl-substituted alkene, carbonyl-substituted alkyne sulfonyl-substituted alkane, sulfonyl-substituted alkene, sulfonyl-substituted alkyne, nitro-substituted alkane, nitro-substituted alkene, nitro-substituted alkyne, sulfonyl halide-substituted alkane, sulfonyl halide-substituted alkene, sulfonyl halide-substituted alkyne, sulfonamide-substituted alkane, sulfonamide-substituted alkene, or sulfonamide-substituted alkyne groups. In other implementations, the precursor (e.g., any herein) can be substituted with one or more functional groups, such as haloaliphatic, haloheteroaliphatic, heteroaliphatic, halo, haloalkyl (e.g., C₁ haloalkyl, including one, two, or three halo substitutions), perfluoroalkyl, alkyl, alkenyl, alkynyl, alkoxy, amide, amine, aminoalkyl, carboxyl, cyano, ester, hydroxyl, hydroxyalkyl, nitro, nitroalkyl, sulfonamide, sulfonate, sulfonyl, sulfonyl halide, and others.

In some implementations, the one or more carbon-containing precursors may include an electron-donating group (e.g., lone pair donor group). The lone pair, such as an oxygen lone pair or nitrogen lone pair, in a precursor molecule may donate electron density to an anti-bonding orbital to enhance radical-activation of the carbon-containing precursor. For example, the one or more carbon-containing precursors includes an alcohol-substituted alkane, alcohol-substituted alkene, alcohol-substituted alkyne, ether-substituted alkane, ether-substituted alkene, ether-substituted alkyne, ether-substituted alkane, ether-substituted alkene, ether-substituted alkyne, O-acyl-substituted alkane, O-acyl-substituted alkene, O-acyl-substituted alkyne, amine-substituted alkane, amine-substituted alkene, amine-substituted alkyne, N-acyl-substituted alkane, N-acyl-substituted alkene, or N-acyl-substituted alkyne group. Yet other non-limiting examples of lone pair donor groups include haloheteroaliphatic, heteroaliphatic, alkoxy, amide, amine, aminoalkyl, ester, hydroxyl, hydroxyalkyl, and others. Any precursor herein can be substituted with one or more lone pair donor groups.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, where the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An example alkenyl includes an optionally substituted C₂-24 alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl.

By “alkoxy” is meant —OR, where R is an optionally substituted aliphatic group, as described herein. Example alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Example unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), where the saturated monovalent hydrocarbon can be derived from removing one hydrogen atom from one carbon atom of a parent compound (e.g., alkane). An alkyl group can be branched, straight-chain, or cyclic (e.g., cycloalkyl). An example alkyl includes a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkoxy (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄-18 aryl, and (d) C₁₋₆ alkyl-C₄-18 aryl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄-18 aryl); and (26) —NR¹R², where each of R¹ and R² is, independently, selected from the group consisting of (a) hydrogen, (b) an N-protecting group, (c) C₁₋₆ alkyl, (d) C₂-6 alkenyl, (e) C₂-6 alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkynyl” is meant an unsaturated monovalent hydrocarbon having at least two carbon atom to 50 carbon atoms (C₂₋₅₀), such as two to 25 carbon atoms (C₂-25), or two to ten carbon atoms (C₂₋₁₀), and at least one carbon-carbon triple bond, where the unsaturated monovalent hydrocarbon can be derived from removing one hydrogen atom from one carbon atom of a parent alkyne. An alkynyl group can be branched, straight-chain, or cyclic (e.g., cycloalkynyl). An example alkynyl includes an optionally substituted C₂-24 alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “amide” is mean —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or where R¹ and R², taken together with the nitrogen atom to which each are attached, can form a heterocyclyl group, as defined herein.

By “amine” is meant —NR¹R², where each of R¹ and R² is, independently, selected from hydrogen, aliphatic, heteroaliphatic, haloaliphatic, haloheteroaliphatic, aromatic, as defined herein, or any combination thereof; or where R¹ and R², taken together with the nitrogen atom to which each are attached, can form a heterocyclyl group, as defined herein.

By “aminoalkyl” is meant an alkyl group, as defined herein, substituted by an amine group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system.

By “carboxyl” is meant a —CO₂H group or an anion thereof.

By “cyano” is meant a —CN group.

By “cycloaliphatic” is meant an aliphatic group, as defined herein, that is cyclic. In particular embodiments, the cycloaliphatic is a cycloalkene, which is a cyclic group having single C—C bonds.

By “ester” is meant —C(O)OR—OC(O)R, where R is selected from aliphatic, heteroaliphatic, haloaliphatic, haloheteroaliphatic, aromatic, as defined herein, or any combination thereof.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “sulfonamide” is meant an —SO₂R, in which R is an amine, as described herein.

By “sulfonate” is meant a —SO₃R group, where R is selected from hydrogen, halo, aliphatic, heteroaliphatic, haloaliphatic, haloheteroaliphatic, aromatic, as defined herein, or any combination thereof.

By “sulfonyl” is meant a —SO₂R group, where R is selected from hydrogen, halo, aliphatic, heteroaliphatic, haloaliphatic, haloheteroaliphatic, aromatic, as defined herein, or any combination thereof.

By “sulfonyl halide” is meant a —SO₂R group, where R is halo.

At block 220 of the process 200, radicals of a source gas are generated, from the source gas, in the remote plasma source that is positioned upstream of the one or more carbon-containing precursors. The radicals may be radicals of hydrogen and generated from a source gas of hydrogen gas (H₂). Alternatively, the radicals may be radicals of oxygen, nitrogen, ammonia, or amine. The source gas may be supplied into the remote plasma source via one or more gas lines. The remote plasma source is located upstream from one or more gas outlets for introducing the one or more carbon-containing precursors into the reaction chamber. The one or more carbon-containing precursors do not pass through the remote plasma source. The remote plasma source may be any suitable plasma source for plasma generation, such as an inductively-coupled plasma source or capacitively-coupled plasma source. Plasma generation in the remote plasma source produces a mixture of ions and radicals, including radicals in an excited energy state.

In some embodiments, the source gas (e.g., H₂) is flowed into the remote plasma source together with one or more additional gases such as an inert gas species. Supplying one or more additional gases may support or stabilize steady-state plasma conditions within the remote plasma source. Inert gas species may include helium (He), neon (Ne), argon (Ar), krypton (Kr), or xenon (Xe). The one or more additional gases may serve as a diluent. In some implementations, hydrogen gas may be supplied with helium gas. As an example, hydrogen gas may be provided in a helium carrier at a concentration of about 1-25% hydrogen or 1-10% hydrogen. Therefore, in some instances, H₂/He plasma is generated in the remote plasma source.

Additionally or alternatively, the one or more additional gases may include a co-reactant gas. A co-reactant gas may include a nitrogen-containing agent (e.g., N₂), oxygen-containing agent (e.g., 02), or combinations thereof. In some embodiments, the co-reactant gas is supplied as a small fraction relative to the source gas. For example, the co-reactant gas may be present with the source gas in a gas mixture at about 0.05% or less by mass, or at about 0.01% or less by mass. That way, radicals generated in the remote plasma source are composed predominantly of radicals of the source gas.

The remote plasma source may be fluidly coupled to the reaction chamber holding the substrate. Radicals and ions are generated within the remote plasma source so that gases, including excited source gas radicals and inert gas radicals and relaxed gases, may flow out of the remote plasma source. These plasma-activated species may encounter a showerhead before entering the reaction chamber. The showerhead may include an ion filter, photon filter, or both. Filtering ions and photons may prevent substrate damage (e.g., via ion bombardment) and undesirable re-excitation of molecules (e.g., via UV excitation).

At block 230 of the process 200, the radicals of the source gas are introduced into the reaction chamber toward the substrate, where the radicals are in an energy state sufficient to activate C—C bonds and/or C—H bonds and form activated carbon radical-containing precursors in an environment adjacent to the substrate. More specifically, the radicals may be in an energy state sufficient to activate C—C bonds, thermodynamically available C—H bonds, C—X (e.g., Br and I) bonds, C—OR bonds, C—NR₂ bonds, and/or C—SR bonds, and form activated carbon radical-containing precursors in the environment adjacent to the substrate. The activated carbon radical-containing precursors deposit to form an amorphous or crystalline carbon film on the substrate. The environment adjacent to the substrate refers to a space immediately above an exposed surface of the substrate in which vapor deposition of activated carbon radical-containing precursors occurs. The radicals of the source gas are delivered into the reaction chamber under process conditions so that excited radicals transition to relaxed radicals without recombining. Pressure, fraction of inert gas species, geometry of gas ports of the showerhead, distance between the showerhead and the one or more gas outlets for delivering carbon-containing precursors, and other process parameters are configured so that the radicals encounter the environment adjacent to the substrate in a low energy state (e.g., ground state) without recombining. In some implementations, all or substantially all of the source gas radicals are hydrogen radicals in the ground state. That way, the substrate is exposed to remote hydrogen plasma that minimizes surface growth damage.

When generated in the remote plasma source, source gas radicals may be in an excited energy state. For example, hydrogen in an excited energy state can have an energy of at least 10.2 eV (first excited state). Excited hydrogen radicals may cause surface growth damage during carbon film growth. In some implementations, when an excited hydrogen radical loses its energy, or relaxes, the excited hydrogen radical may transition to a substantially low energy state hydrogen radical or ground state hydrogen radical. In some embodiments, process conditions may be provided so that excited hydrogen radicals lose energy or relax to form ground state hydrogen radicals. For example, the remote plasma source and associated components may be designed so that a residence time of radicals diffusing from the remote plasma source to the substrate is greater than the energetic relaxation time of an excited radical. The energetic relaxation time for an excited hydrogen radical can be equal to or less than about 1×10⁻³ seconds.

The showerhead may disperse and diffuse radicals exiting the remote plasma source into the reaction chamber while limiting or filtering ions. In some embodiments, the showerhead may be a multiport gas distributor with an array of spaced-apart holes or channels. In some embodiments, dimensions of showerhead holes or gas ports may promote radical relaxation to lower energy states while limiting recombination.

In some implementations, all or a substantial fraction of the source gas radicals are in the ground state, e.g., at least about 90% or 95% of the source gas radicals in the environment adjacent to the substrate are in the ground state. The source gas radicals may be hydrogen radicals, where hydrogen radicals may also be referred to as “radicals of hydrogen” or “hydrogen atom radicals.” A state in which a substantial fraction of the source gas radicals are in the ground state can be achieved by various techniques. Some plasma apparatuses, such as described in FIG. 3, are designed to achieve this state. The process conditions for achieving hydrogen radicals in the ground state may achieve conditions free of substantial amounts of ions, electrons, or excited radical species. The presence of substantial amounts of ions or excited radicals can cause surface growth damage to the substrate. In some implementations, a concentration of ions in the environment adjacent to the substrate is no greater than about 10⁷/cm³. Source gas radicals in the ground state provide mild reaction conditions in the environment adjacent to the substrate.

The carbon-containing precursors are flowed into the reaction chamber downstream from the showerhead of the remote plasma source in which the radicals are introduced. Source gas radicals are generated in the remote plasma source located upstream from the one or more gas outlets for delivering the carbon-containing precursors. By the time the source gas radicals encounter the carbon-containing precursors, the source gas radicals are in a low energy state or ground state upon mixing or interacting with the carbon-containing precursors. In some implementations, hydrogen radicals transition to the ground state in a transition space above the one or more gas outlets, and interact and mix with the carbon-containing precursors in a deposition space below the one or more gas outlets. Radicals generated from a remote plasma source that interact with downstream carbon-containing precursors provide an indirect plasma-based deposition technique based on activated carbon-containing precursors.

The deposition space below the one or more gas outlets includes the environment adjacent to the substrate. The environment adjacent to the substrate includes the exposed surface of the substrate as well as the source gas radicals in the low energy state (e.g., ground state) and the carbon-containing precursors immediately above the exposed surface. In some implementations, the distance above the exposed surface of the substrate may be up to about 100 mm or up to about 15 mm above the exposed surface of the substrate. In effect, activation of the carbon-containing precursors by the radicals in the low energy state occur at a small distance above the exposed surface of the substrate. Typically, reaction conditions in the environment adjacent to the substrate are generally uniform across the entire exposed surface of the substrate, though some variation may be permitted.

PECVD or other direct plasma deposition techniques generate plasma-activated species of carbon-containing precursors that unselectively cleave precursor bonds. This breaks down the precursors into less stable molecules and makes otherwise unstable reaction pathways accessible. The PECVD or other direct plasma deposition techniques produce ions or highly reactive radicals or other fragment types that make film properties of the carbon film difficult to predict. By unselectively breaking precursor bonds, for example, highly reactive radicals or fragment types having high sticking coefficients are produced. This can lead to dangling bonds that result in carbon films having poor step coverage. This can also result in uncontrolled chemical or morphological structures in the carbon films. Moreover, direct plasma conditions create a lot of ion bombardment at the surface of the substrate that otherwise causes surface growth damage.

Deposition of dense amorphous carbon films can be achieved on planar or blanket applications using conventional deposition techniques. However, deposition of dense amorphous carbon films is challenging on substrate features having a depth-to-width aspect ratio greater than about 2:1. Using conventional plasma-based deposition techniques will ordinarily cause some carbon-containing ions to exist in the environment adjacent to the substrate that changes the composition and density of the carbon film. If conformality is controlled to any degree, the conformality of the film is coupled to the power applied to the plasma. In addition, carbon films deposited by PECVD or other conventional deposition techniques may have a high content of sp2 bonding, which can adversely impact optical transparency and undermine etch selectivity. Controlling the surface chemistry of carbon to form C—C bonds without forming other bond partners is thermodynamically difficult. Most deposition techniques involving carbon-containing precursors do not convert C—H bonds or C—X (e.g., where X is a halide or other functional group) bonds to C—C bonds.

The present disclosure utilizes source gas radicals generated in a remote plasma source to transition to low energy state radicals to activate carbon-containing precursors for carbon film deposition. The low energy state radicals selectively break or cleave certain bonds in a carbon-containing precursor molecule to result in activated carbon-containing precursors. Without being limited by any theory, one of the more kinetically favorable reaction mechanisms in the deposition reaction can include hydrogen abstraction, which pulls hydrogen from C—H bonds in a hydrocarbon precursor, generating H₂ gas, and results in a carbon centered radical on the activated hydrocarbon precursor. Without being limited by any theory, another kinetically favorable reaction mechanism in the deposition reaction can involve low energy state radicals interacting with alkene or alkyne groups in the carbon-containing precursor, adding across the double or triple bond, to form a new C—H bond and a carbon centered radical in the activated alkanes, for alkene or alkyne starting groups, or alkenes, for alkyne starting groups. Without being limited by any theory, another kinetically favorable reaction mechanism in the deposition reaction can include selective bond-breaking of C—X bonds that results in an activated carbon-containing precursor, where X can be a halide or other electron-withdrawing functional group. This mechanism is similar is sequence to the abstraction mechanism, a new X—H bond is formed, while at the same time a carbon centered radical is formed on the carbon-containing precursor. Without being limited by any theory, another kinetically favorable reaction mechanism in the deposition reaction can include lone pair donation in which an oxygen lone pair, nitrogen lone pair, or other lone pair weakens a C—X bond (where X is H, halide or other electron-withdrawing functional group), which in turn undergoes abstraction by a hydrogen radical, generating H—X and a carbon centered radical on the carbon-containing precursor molecule. Activated carbon-containing precursors have active sites that promote bonding and cross-linking to form carbon-to-carbon bonds. Bonding at the active sites and cross-linking can form a primary backbone or matrix in a resulting carbon film. Thus, activated alkanes, activated alkenes, activated alkynes, or other activated carbon-based molecules in the environment adjacent to the substrate may react with one another to deposit the crystalline or amorphous carbon film. In some cases, what is deposited is an amorphous hydrogenated carbon film.

Various functional groups may substitute the carbon-containing precursor to weaken bond strengths in the one or more C—C bonds, C—H bonds, C—N bonds, C—OH bonds, or C—X bonds (where X represents a halogen). In some embodiments, the functional group may be an electron-withdrawing group or an electron-donating group as described above. Hydrogen radicals in a low energy state may selectively activate a weakened C—C single bond, weakened C—H bond, weakened C—N bond, and/or weakened C—X bond. Additionally or alternatively, hydrogen radicals in a low energy state may selectively activate a C═C double bond and/or C—C triple bond. The presence of weakened bonds, double bonds, or triple bonds in the carbon-containing precursor renders the carbon-containing precursor vulnerable to radical-based activation.

The carbon-containing precursors do not serve as passive spectators, but significantly contribute to the composition of the amorphous or crystalline carbon film. In some implementations, substantially all or a substantial fraction of atoms in the carbon film are provided by the carbon-containing precursors, with small amounts of source gas species, inert gas species, or other chemical species providing less than about 10 atomic %, less than about 5 atomic %, or less than about 2 atomic % of the film mass. In such cases, low energy hydrogen atom radicals used to drive the deposition reaction do not substantially contribute to the mass of the deposited carbon film. Thus, the depositing species in the present disclosure is primarily the carbon-containing precursors. In contrast, other conventional plasma-based deposition processes generate ions as well as neutrals as depositing species.

Carbon-containing precursors are activated to form carbon radicals that serve as depositing species on the substrate. The deposition process conditions may provide relatively mild conditions in the environment adjacent to the substrate for radical activation of the carbon-containing precursors. The carbon-containing precursors are activated by low energy state radicals generated upstream from the carbon-containing precursors. The carbon radicals interact with nucleation sites on the surface of the substrate to deposit crystalline or amorphous carbon film on the substrate. In some embodiments, what is deposited is an amorphous hydrogenated carbon film.

The source gas radicals interact with the carbon-containing precursors to not only generate activated carbon-containing precursors, but to also simultaneously etch carbon film during carbon film deposition. Process conditions are controlled so that carbon film deposition proceeds at a faster rate than carbon film etching. In some implementations, the source gas radicals etch portions of the carbon film that are poorer in quality. For example, hydrogen radicals etch portions of an amorphous carbon film that are poorer in quality to create more crystalline diamond-like carbon. Without being limited by any theory, the hydrogen radicals may be used to reduce sp2 bonding and increase sp3 bonding, and the hydrogen radicals may be used to decrease hydrogen content and increase density in the carbon film. Process conditions may be controlled to tune properties associated with density, hydrogen content, conformality, sp2 to sp3 bonding, hardness, and other film properties. The process conditions may affect the behavior of source gas radical interaction with the carbon-containing precursors.

The temperature in the environment adjacent to the exposed surface of the substrate can be any suitable temperature facilitating the deposition reaction. In some implementations, the temperature may be largely controlled by a temperature of a pedestal on which a substrate is supported. Ordinarily, high-quality crystalline carbon films or amorphous carbon films with high sp2 bonding (highly graphitic) or high sp3 bonding (diamond-like) require extremely high temperatures in conventional deposition temperatures and/or plasma. Such high temperatures may typically exceed about 550° C. or exceed about 650° C. In some implementations, when performing radical-activated carbon film deposition in the present disclosure, an operating temperature may be equal to or less than about 550° C., equal to or less than about 500° C., equal to or less than about 450° C., equal to or less than about 400° C., equal to or less than about 350° C., equal to or less than about 300° C., between about 50° C. and about 550° C., or between about 200° C. and about 400° C. Such temperatures may be suitable for semiconductor applications. Even at such temperatures, high-quality crystalline carbon films such as graphene or amorphous carbon films with high sp2 bonding or high sp3 bonding may be obtained. Higher temperatures generally increase an etch rate associated with source gas radical interaction with deposited carbon film. By way of an example, amorphous carbon films can be deposited at a reasonable deposition rate at temperatures up to about 100° C. using hydrocarbon precursors including alkenes, but amorphous carbon films can be deposited at a reasonable deposition rate at temperatures exceeding 100° C. using hydrocarbon precursors including alkynes. In some implementations, a deposition rate of the carbon film can be equal to or greater than about 4 Å per minute, equal to or greater than about 8 Å per minute, or equal to or greater than about 25 Å per minute. The temperature in the environment adjacent to the substrate is selected to promote radical-activated carbon film deposition while limiting etch of the deposited carbon film.

The pressure in the environment adjacent to the metal surface of the substrate can be any suitable pressure to promote carbon film growth in the reaction chamber. Typically, high-quality crystalline carbon films or amorphous carbon films with high sp2 bonding or high sp3 bonding require extremely high pressures in conventional deposition temperatures and/or plasma. Such high pressures may typically exceed about 10 Torr or exceed about 50 Torr. In some implementations, when performing radical-activated carbon film deposition in the present disclosure, an operating pressure may be about 10 Torr or lower, or about 5 Torr or lower. For example, the operating pressure may be between about 1 Torr and about 2 Torr.

In some implementations, the RF power applied for generating radicals in the remote plasma source may be controlled. The RF power may be sufficient for plasma generation and supply of ions and radicals while limiting ion bombardment during deposition. It will be understood that the RF power may depend on the plasma apparatus design and type. By way of an example, an RF power supply may apply power in a range between about 1 kW and about 6 kW in an inductively-coupled plasma generator for generating hydrogen radicals in the remote plasma source.

In some implementations, a gap distance between the showerhead of the remote plasma source and the pedestal may be controlled. The gap distance may be optimized to afford sufficient time for source gas radicals to transition from an excited state to a relaxed state prior to reaching the environment adjacent to the substrate. Furthermore, the showerhead may be separated from the one or more gas outlets for delivering the carbon-containing precursors by a sufficient distance to prevent back diffusion or back streaming of the carbon-containing precursors. In some implementations, one or more gas outlets may be separated from the showerhead by a distance between about 12 mm and about 150 mm, between about 15 mm and about 100 mm, or between about 20 mm and about 70 mm.

In some implementations, gas flow rates of the precursor gases and source gases may be controlled to influence carbon film deposition. By way of an example, hydrogen and helium gases may be flowed into the remote plasma source as a mixture, in a flow rate range between about 2 and about 40 standard liters per minute (slm), between about 5 and about 25 slm, or between about 10 slm and about 20 slm. A mixture of hydrogen and helium may be in a steady-state concentration between about 1 vol. % and about 99 vol. % hydrogen gas in helium, or between about 1 vol. % and about 10 vol. % hydrogen gas in helium. In some implementations, the carbon-containing precursors may be supplied into the reaction chamber in a flow rate range between about 0.5 and about 50 standard cubic centimeters per minute (sccm), between about 1 and about 25 sccm, or between about 1 and about 10 sccm. It will be understood that in some implementations, a source gas of hydrogen may be flowed without any accompanying inert gas so that the source gas is delivered with 100 vol. % hydrogen gas.

One or more deposition process conditions may be controlled to influence various aspects of carbon film deposition (e.g., deposition rate) and film properties (e.g., hardness, density, conformality, hydrogen content, etc.). It will be understood that the deposition process conditions described above are not intended to be limiting and that different or additional deposition process conditions may be controlled to influence carbon film deposition.

In some implementations, the carbon film may have a step coverage equal to or greater than about 90%, equal to or greater than about 95%, or equal to or greater than about 99%. Such a high step coverage may be achieved where the substrate has recessed features equal to or greater than about 3:1, equal to or greater than about 5:1, equal to or greater than about 7:1, or equal to or greater than about 10:1. Step coverage may be calculated by comparing the average thickness of deposited carbon film on a bottom, sidewall, or top of a feature to an average thickness of the deposited carbon film on another location of the feature (i.e., bottom, sidewall, or top of the feature). For example, step coverage may be calculated by dividing the average thickness of the deposited carbon film on the sidewall by the average thickness of the deposited carbon film at the top of the feature and multiplying the value by 100 to obtain a percentage. Accordingly, radical-activated carbon film deposition of the present disclosure may achieve ALD-like conformality in carbon films such as amorphous hydrogenated carbon films.

In some implementations, radical-activated carbon film deposition in the present disclosure may deposit carbon films having a desired amount of sp2 to sp3 bonding and hydrogen content. That way, not only can highly graphitic or diamond-like films be deposited but various types of amorphous carbon films can be deposited. An amount of sp3 carbon bonding in the carbon film may be anywhere between 0% and 100%. In some embodiments, an amount of sp3 carbon bonding in the carbon film is equal to or greater than about 25%. In some implementations, an amount of sp3 carbon bonding in the carbon film is equal to or greater than about 40%. In contrast, many conventional plasma-based or thermal-based deposition techniques result in carbon films having mostly sp2 carbon bonding (i.e., low sp3 carbon bonding). Many such conventional plasma-based or thermal-based deposition techniques result in carbon films having high hydrogen content unless exceedingly high temperatures are applied or direct plasma is applied. The carbon film of the present disclosure may be deposited with low hydrogen content. In some embodiments, a hydrogen content in the carbon film is equal to or less than about 70 atomic %, between about 10 atomic % and about 70 atomic %, or between about 20 atomic % and about 70 atomic %.

In some implementations, a density of the carbon film deposited by radical-activation is controlled to a desired level. For instance, the density of the carbon film is between about 1.1 g/cm³ and about 3.5 g/cm³. In some implementations, a refractive index of the carbon film deposited by radical-activation is controlled to a desired level. For example, the refractive index of the carbon film is between about 1.5 and about 2.5. In some implementations, a hardness of the carbon film deposited by radical-activation is controlled to a desired level. Specifically, the hardness of the carbon film is between about 1 GPa and about 80 GPa. Some or all of the foregoing properties may be tuned by varying the amount of sp3 bonding and/or hydrogen content in the carbon film. Other properties of the carbon film (e.g., intrinsic stress, extinction coefficient, band gap, etch selectivity) may be tuned by varying amounts of sp3 bonding and/or hydrogen content.

A wide range of carbon films may be deposited by radical activation. The carbon films are undoped. Specifically, the carbon films of the present disclosure do not include metal-doped carbon films, oxygen-doped, nitrogen-doped carbon, or silicon-doped carbon. In certain instances, an amorphous hydrogenated carbon film may be deposited that is highly conformal, having a low hydrogen content, and having a high amount of sp3 bonding. For example, the amorphous hydrogenated carbon film may have a step coverage over recessed features that is at least 90%, having a hydrogen content that is between about 20 atomic % and about 70 atomic %, and having an amount of sp3 carbon bonding that is greater than about 25%.

The crystalline or amorphous carbon film is deposited on the exposed surface of the substrate. Carbon film deposited by radical activation may selectively occur on certain materials. In some implementations, the carbon film is selectively deposited on a metal such as copper, cobalt, molybdenum, tungsten, or ruthenium. The metal may serve as a catalyst for promoting nucleation of carbon on the metal surface. Selective deposition on metal surface may occur for crystalline carbon films such as graphene. In some implementations, the carbon film is deposited on a non-metal layer. Thus, amorphous carbon films may be deposited on non-metal layers such as silicon oxides, silicon nitrides, silicon, or carbon. In fact, amorphous carbon films may be grown on other carbon films such as high sp2 content carbon film. Without being limited by any theory, amorphous carbon films of the present disclosure may be grown on non-metal layers via carbon center radicals generated in the gas phase. Amorphous carbon films may alternatively be deposited on metal layers such as copper, tungsten, molybdenum, or ruthenium. Such deposition may or may not be assisted by interaction of metal with carbon. Amorphous carbon films deposited by radical-activation are not limited to selective deposition on metal surfaces, but may be deposited on various metal or non-metal surfaces. Deposition on metal or non-metal (e.g., dielectric) surfaces may depend on the deposition temperature. On certain materials and at certain temperatures, etching by source gas radicals (e.g., hydrogen radicals) may proceed faster than deposition. Thus, the temperature may be low enough so that deposition can exceed etching on materials such as silicon oxides, silicon nitrides, high sp2 content carbon, and silicon. For instance, the temperature may be equal to or less than about 150° C. for amorphous carbon film deposition on silicon oxides, silicon nitrides, high sp2 content carbon, or silicon.

One aspect of the disclosure is an apparatus configured to accomplish the radical-activated carbon film deposition methods described herein. A suitable apparatus includes hardware for accomplishing the process operations and a system controller having instructions for controlling process operations in accordance with the present disclosure. In some implementations, the apparatus for performing the aforementioned process operations can include a remote plasma source. A remote plasma source provides mild reaction conditions compared to a direct plasma. An example of a suitable remote plasma apparatus is described in U.S. patent application Ser. No. 14/062,648, filed Oct. 24, 2013, which is incorporated herein by reference in its entirety and for all purposes.

FIG. 3 illustrates a schematic diagram of an example plasma processing apparatus with a remote plasma source according to some implementations. The plasma processing apparatus 300 includes the remote plasma source 302 separated from a reaction chamber 304. The remote plasma source 302 is fluidly coupled with the reaction chamber 304 via a showerhead 306, which may also be referred to as a multiport gas distributor. Radical species are generated in the remote plasma source 302 and supplied to the reaction chamber 304. One or more carbon-containing precursors are supplied to the reaction chamber 304 downstream from the remote plasma source 302 and downstream from the showerhead 306. The one or more carbon-containing precursors react with the radical species in a chemical vapor deposition zone 308 of the reaction chamber 304 to deposit a carbon film on a front surface of a substrate 312. The chemical vapor deposition zone 308 includes an environment adjacent to the front surface of the substrate 312, where the front surface of the substrate 312 faces the remote plasma source 302.

The substrate 312 is supported on a substrate support or pedestal 314. The pedestal 314 may move within the reaction chamber 304 to position the substrate 312 within the chemical vapor deposition zone 308. In the embodiment shown in FIG. 3, pedestal 314 is shown having elevated the substrate 310 within the chemical vapor deposition zone 308. The pedestal 314 may also adjust the temperature of the substrate 312 in some embodiments, which can provide some selective control over thermally activated surface reactions on the substrate 312.

FIG. 3 shows a coil 318 arranged around the remote plasma source 302, where the remote plasma source 302 includes an outer wall (e.g., quartz dome). The coil 318 is electrically coupled to a plasma generator controller 322, which may be used to form and sustain plasma within a plasma region 324 via inductively coupled plasma generation. In some implementations, the plasma generator controller 322 may include a power supply for supplying power to the coil 318, where the power can be in a range between about 1 and 6 kW during plasma generation. In some implementations, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 324, radical species may continuously be generated using plasma excitation during film deposition. In some implementations, hydrogen radicals are generated under approximately steady-state conditions during steady-state film deposition, though transients may occur at the beginning and end of film deposition.

A supply of radicals may be continuously generated within the plasma region 324 while hydrogen gas or other source gas is being supplied to the remote plasma source 302. Excited radicals may be generated in the remote plasma source 302. If not re-excited or re-supplied with energy, or re-combined with other radicals, the excited radicals lose their energy, or relax. Thus, excited radicals may relax to form radicals in a substantially low energy state or ground state.

The hydrogen gas (H₂) or other source gas may be diluted with one or more additional gases. These one or more additional gases may be supplied to the remote plasma source 302. In some implementations, the hydrogen gas or other source gas is mixed with one or more additional gases to form a gas mixture, where the one or more additional gases can include a carrier gas. Non-limiting examples of additional gases can include helium (He), neon (Ne), argon (Ar), krypton (Kr), xenon (Xe), and nitrogen (N₂). The one or more additional gases may support or stabilize steady-state plasma conditions within the remote plasma source 302 or aid in transient plasma ignition or extinction processes. In some implementations, diluting hydrogen gas or other source gas with helium, for example, may permit higher total pressures without concomitant plasma breakdown. Put another way, a dilute gas mixture of hydrogen gas and helium may permit higher total gas pressure without increasing plasma power to the remote plasma source 302. In certain embodiments, hydrogen gas is provided in a carrier such helium. As an example, hydrogen gas may be provided in a helium carrier at a concentration of about 1-25% hydrogen or about 1-10% hydrogen.

As shown in FIG. 3, a source gas supply 326 is fluidly coupled with the remote plasma source 302 for supplying the hydrogen gas or source gas. In addition, an additional gas supply 328 is fluidly coupled with the remote plasma source 302 for supplying the one or more additional gases. The one or more additional gases may also include a co-reactant gas. While the embodiment in FIG. 3 depicts the gas mixture of the source gas and the one or more additional gases being introduced through separate gas outlets, it will be understood that the gas mixture may be introduced directly into the remote plasma source 302. That is, a pre-mixed dilute gas mixture may be supplied to the remote plasma source 302 through a single gas outlet.

Gases, such as excited hydrogen and helium radicals and relaxed gases/radicals, flow out of the remote plasma source 302 and into the reaction chamber 304 via the showerhead 306. Gases within the showerhead 306 and within the reaction chamber 304 are generally not subject to continued plasma excitation therein. In some implementations, the showerhead 306 includes an ion filter and/or a photon filter. Filtering ions and/or photons may reduce substrate damage, undesirable re-excitation of molecules, and/or selective breakdown or decomposition of hydrocarbon precursors within the reaction chamber 304. Showerhead 306 may have a plurality of gas ports 334 to diffuse the flow of gases into the reaction chamber 304. In some implementations, the plurality of gas ports 334 may be mutually spaced apart. In some implementations, the plurality of gas ports 334 may be arranged as an array of regularly spaced apart channels or through-holes extending through a plate separating the remote plasma source 302 and the reaction chamber 304. The plurality of gas ports 334 may smoothly disperse and diffuse exiting radicals from the remote plasma source 302 into the reaction chamber 304.

Typical remote plasma sources are far removed from reaction vessels. Consequently, radical extinction and recombination, e.g., via wall collision events, may reduce active species substantially. In contrast, in some implementations, dimensions for the plurality of gas ports 334 may be configured in view of the mean free path or gas flow residence time under typical processing conditions to aid the free passage of radicals into the reaction chamber 304. In some implementations, openings for the plurality of gas ports 334 may occupy between about 5% and about 20% of an exposed surface area of the showerhead 306. In some implementations, the plurality of gas ports 334 may each have an axial length to diameter ratio of between about 3:1 and 10:1 or between about 6:1 and about 8:1. Such aspect ratios may reduce wall-collision frequency for radical species passing through the plurality of gas ports 334 while providing sufficient time for a majority of excited state radical species to relax to ground state radical species. In some implementations, dimensions of the plurality of gas ports 334 may be configured so that the residence time of gases passing through the showerhead 306 is greater than the typical energetic relaxation time of an excited state radical species. Excited state radical species for hydrogen source gas may be denoted by ·H* in FIG. 3 and ground state radical species for hydrogen source gas may be denoted by ·H in FIG. 3.

In some implementations, excited state radical species exiting the plurality of gas ports 334 may flow into a relaxation zone 338 contained within an interior of the reaction chamber 304. The relaxation zone 338 is positioned upstream of the chemical vapor deposition zone 308 but downstream of the showerhead 306. Substantially all or at least 90% of the excited state radical species exiting the showerhead 306 will transition into relaxed state radical species in the relaxation zone 338. Put another way, almost all of the excited state radical species (e.g., excited hydrogen radicals) entering the relaxation zone 338 become de-excited or transition into a relaxed state radical species (e.g., ground state hydrogen radicals) before exiting the relaxation zone 338. In some implementations, process conditions or a geometry of the relaxation zone 338 may be configured so that the residence time of radical species flowing through the relaxation zone 338, e.g., a time determined by mean free path and mean molecular velocity, results in relaxed state radical species flowing out of the relaxation zone 338.

With the delivery of radical species to the relaxation zone 338 from the showerhead 306, one or more carbon-containing precursors may be introduced into the chemical vapor deposition zone 308. The one or more carbon-containing precursors may be introduced via a gas distributor or gas outlet 342, where the gas outlet 342 may be fluidly coupled with a precursor supply source 340. The relaxation zone 338 may be contained within a space between the showerhead 306 and the gas outlet 342. The gas outlet 342 may include mutually spaced apart openings so that the flow of the one or more carbon-containing precursors may be introduced in a direction parallel with gas mixture flowing from the relaxation zone 338. The gas outlet 342 may be located downstream from the showerhead 306 and the relaxation zone 338. The gas outlet 342 may be located upstream from the chemical vapor deposition zone 308 and the substrate 312. The chemical vapor deposition zone 308 is located within the interior of the reaction chamber 304 and between the gas outlet 342 and the substrate 312.

Substantially all of the flow of the one or more carbon-containing precursors may be prevented from mixing with excited state radical species adjacent to the showerhead 306. Relaxed or ground state radical species mix in a region adjacent to the substrate 312 with the one or more carbon-containing precursors. The chemical vapor deposition zone 308 includes the region adjacent to the substrate 312 where the relaxed or ground state radical species mix with the one or more carbon-containing precursors. The relaxed or ground state radical species mix with the one or more carbon-containing precursors in the gas phase during CVD formation of graphene.

In some implementations, a co-reactant may be introduced from the showerhead 306 and flowed along with the radical species generated in the remote plasma source 302 and into the reaction chamber 304. This may include radicals and/or ions of a co-reactant gas provided in the remote plasma source 302. The co-reactant may be supplied from the additional gas supply 328. In some implementations, the co-reactant may include a nitrogen-containing agent such as nitrogen gas (N₂). For example, radicals and/or ions of nitrogen may be generated and flowed with the radical species of hydrogen during pretreatment of an exposed surface of the substrate 312.

The gas outlet 342 may be separated from the showerhead 306 by a sufficient distance to prevent back diffusion or back streaming of the one or more carbon-containing precursors. This can afford sufficient time for radical species of hydrogen to transition from an excited state to a relaxed state (e.g., ground state). In some implementations, the gas outlet 342 may be separated from the plurality of gas ports 334 by a distance between about 12 mm and about 150 mm, between about 15 mm and about 100 mm, or between about 20 mm and about 70 mm.

Process gases may be removed from the reaction chamber 304 via an outlet 348 that is fluidly coupled to a pump (not shown). Thus, excess carbon-containing precursors, co-reactants, radical species, and diluent and displacement or purge gases may be removed from the reaction chamber 304. In some implementations, a system controller 350 is in operative communication with the plasma processing apparatus 300. In some implementations, the system controller 350 includes a processor system 352 (e.g., microprocessor) configured to execute instructions held in a data system 354 (e.g., memory). In some implementations, the system controller 350 may be in communication with the plasma generator controller 322 to control plasma parameters and/or conditions. In some implementations, the system controller 350 may be in communication with the pedestal 314 to control pedestal elevation and temperature. In some implementations, the system controller 350 may control other processing conditions, such as RF power settings, frequency settings, duty cycles, pulse times, pressure within the reaction chamber 304, pressure within the remote plasma source 302, gas flow rates from the source gas supply 326 and the additional gas supply 328, gas flow rates from the precursor supply source 340 and other sources, temperature of the pedestal 314, and temperature of the reaction chamber 304, among others.

The system controller 350 may contain instructions for controlling process conditions for the operation of the plasma processing apparatus 300. The system controller 350 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the system controller 350 or they may be provided over a network.

In certain embodiments, the system controller 350 controls all or most activities of the plasma processing apparatus 300 described herein. For example, the system controller 350 may control all or most activities of the plasma processing apparatus 300 associated with radical-activated carbon film deposition and, optionally, other operations in a fabrication flow that includes the carbon film. The system controller 350 may execute system control software including sets of instructions for controlling the timing, gas composition, gas flow rates, chamber pressure, chamber temperature, RF power levels, substrate position, and/or other parameters. Other computer programs, scripts, or routines stored on memory devices associated with the system controller 350 may be employed in some embodiments. To provide relatively mild reactive conditions at the environment adjacent to the substrate 312, parameters such as the RF power levels, gas flow rates to the plasma region 324, gas flow rates to the chemical vapor deposition zone 308, and timing of the plasma ignition can be adjusted and maintained by system controller 350. Additionally, adjusting the substrate position may further reduce the presence of high-energy radical species at the environment adjacent to the substrate 312. In a multi-station reactor, the system controller 350 may comprise different or identical instructions for different apparatus stations, thus allowing the apparatus stations to operate either independently or synchronously.

In some embodiments, the system controller 350 may include instructions for performing operations such as flowing carbon-containing precursors through the gas outlet 342 into the reaction chamber 304, providing a source gas into the remote plasma source 302, generating radical species of the source gas in the remote plasma source 302 upstream of the one or more carbon-containing precursors, introducing the radical species from the remote plasma source 302 into the reaction chamber 304 to react with the carbon-containing precursors to deposit a crystalline or amorphous carbon film on the substrate 312. The carbon-containing precursors may include one or more C—C bonds and/or one or more C—H bonds. The radical species in the reaction chamber 304 in an environment adjacent to the substrate 312 may be hydrogen radicals in an energy state sufficient to activate the one or more C—C bonds and/or the one or more C—H bonds to form activated carbon-containing precursors. In some implementations, the system controller 350 may include instructions for maintaining a temperature of the substrate 312 between about 50° C. and about 550° C. In some implementations, each of the carbon-containing precursors includes a linear, branched, or cyclic alkene or alkyne group. In some implementations, each of the carbon-containing precursors includes a branched or cyclic alkane group.

In some embodiments, the apparatus 300 may include a user interface associated with system controller 350. The user interface may include a display screen, graphical software displays of the apparatus 300 and/or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the system controller. The signals for controlling the process are output on the analog and digital output connections of the processing system.

In general, the methods described herein can be performed on systems including semiconductor processing equipment such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. In general, the electronics are referred to as the system controller, which may control various components or subparts of the system or systems. The system controller, depending on the processing requirements and/or the type of system, may be programmed to control any of the processes disclosed herein, including the delivery of processing gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials (e.g., silicon carbide), surfaces, circuits, and/or dies of a wafer.

The system controller, in some implementations, may be a part of or coupled to a computer that is integrated with, coupled to the system, otherwise networked to the system, or a combination thereof. For example, the system controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller receives instructions in the form of data, which specify parameters for each of the processing steps to be performed during one or more operations. It should be understood that the parameters may be specific to the type of process to be performed and the type of tool that the system controller is configured to interface with or control. Thus as described above, the system controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In addition to crystalline or amorphous carbon film deposition described herein, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

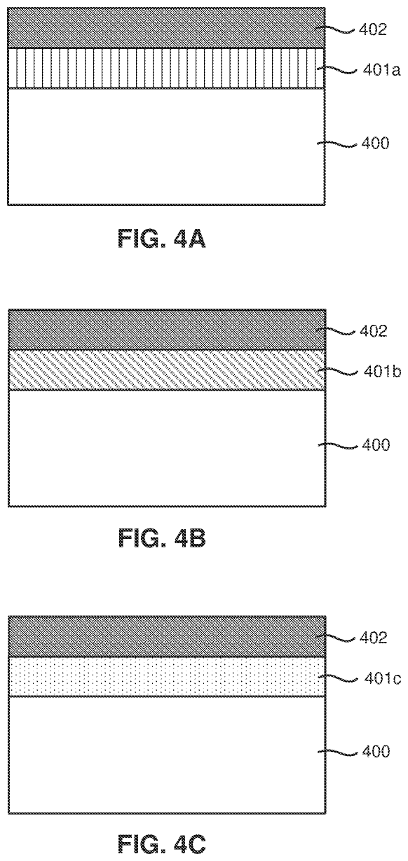

FIG. 4A illustrates a cross-sectional schematic of an example carbon film deposited on a dielectric layer of a substrate. An amorphous carbon film 402 can be formed under process conditions producing a relatively mild environment adjacent to a substrate 400. The substrate 400 can be any wafer, semiconductor wafer, partially fabricated integrated circuit, printed circuit board, display screen, or other appropriate workpiece. A dielectric layer 401a may be formed on the substrate 400. The dielectric layer 401a may be composed of silicon oxide or silicon nitride. Or, the dielectric layer 401a may be composed of a carbon layer such as a DLC film layer. The amorphous carbon film 402 may be deposited on the dielectric layer 401a by radical-activated carbon film deposition as described above. Radicals are generated in a remote plasma source and carbon-based precursors are flowed into a reaction chamber via gas outlets positioned downstream from the remote plasma source. The radicals selectively activate specific bonds in the carbon-based precursors, such as C—C bonds or C—H bonds, to form carbon radicals. The carbon radicals provide active sites for deposition of the amorphous carbon film 402. Process conditions and selection of the carbon-based precursor can drastically alter the properties of the amorphous carbon film 402.

FIG. 4B illustrates a cross-sectional schematic of an example carbon film deposited on a semiconducting layer of a substrate. A semiconducting layer 401b may be formed on the substrate 400. The semiconducting layer 401b may be composed of doped or undoped silicon. The amorphous carbon film 402 may be deposited on the semiconducting layer 401b by radical-activated carbon film deposition as described above.

FIG. 4C illustrates a cross-sectional schematic of an example carbon film deposited on a metal layer of a substrate. A metal layer 401c may be formed on the substrate 400. The metal layer 401c may be composed of a suitable metal such as copper, tungsten, molybdenum, cobalt, or ruthenium. The metal layer 401c may serve as a catalyst to promote nucleation of bulk carbon, especially more graphitic carbon having high sp2 bonding. The amorphous carbon film 402 may be deposited on the metal layer 401c by radical-activated carbon film deposition as described above.

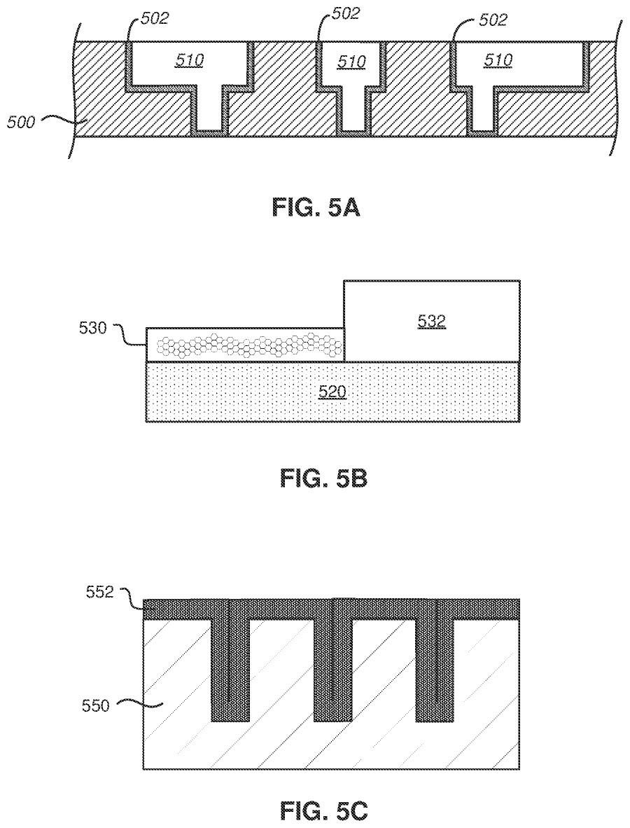

FIG. 5A illustrates a cross-sectional schematic of an example carbon film as a liner layer deposited in a dual damascene structure. As illustrated in FIG. 5A, a dielectric layer 500 can have a plurality of trenches or vias 510 cut into the dielectric layer 500. Amorphous carbon film 502 can be deposited along the trenches or vias 510, where the amorphous carbon film 502 may serve as a liner layer, adhesion layer, etch stop, and/or barrier layer in the dual damascene structure. The trenches or vias 510 may be subsequently filled with metal.

FIG. 5B illustrates a cross-sectional schematic of an example carbon film as a deposition inhibitor on a substrate. In FIG. 5B, an amorphous carbon film 530 is deposited on a top surface of a substrate 520. The top surface of the substrate 520 may be a non-metal or metal surface. A material layer 532 is deposited over the substrate 520 without depositing on the amorphous carbon film 530. In some implementations, the material layer 532 is a metal, metal oxide, or metal nitride.

FIG. 5C illustrates a cross-sectional schematic of an example conformal carbon film as a gapfill in recessed features. In FIG. 5C, an amorphous carbon film 552 serves as gap fill in recessed features of a substrate 550.

Crystalline or amorphous carbon films formed by radical-activated carbon film deposition as described above may be employed as liners, gap-fill, deposition inhibitors, and selective deposition.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of depositing an amorphous or crystalline carbon film on a substrate, the method comprising:
flowing one or more carbon-containing precursors into a reaction chamber toward a substrate in the reaction chamber, each of the carbon-containing precursors having at least one of: one or more C—C bonds or one or more C—H bonds;
generating, from a source gas, radicals of the source gas in a remote plasma source that is positioned upstream of the one or more carbon-containing precursors; and
introducing the radicals of the source gas into the reaction chamber toward the substrate, wherein the radicals are in an energy state sufficient to activate C—C bonds and/or C—H bonds and form activated carbon radical-containing precursors in an environment adjacent to the substrate, wherein the activated carbon radical-containing precursors deposit to form an amorphous or crystalline carbon film on the substrate.

2. The method of claim 1, wherein the source gas comprises hydrogen gas and the radicals of the source gas are radicals of hydrogen.

3. The method of claim 2, wherein the radicals of hydrogen are radicals of hydrogen in a ground state in an environment adjacent to the substrate.

4. The method of claim 1, wherein the substrate comprises a non-metal layer of silicon oxide, silicon nitride, silicon, or carbon, and the amorphous or crystalline carbon film being deposited on the non-metal layer.

5. The method of claim 1, wherein the substrate comprises a metal layer of copper, cobalt, molybdenum, tungsten, or ruthenium, and the amorphous or crystalline carbon film being deposited on the metal layer.

6. The method of claim 1, wherein the one or more carbon-containing precursors comprise at least one of a linear alkene, linear alkyne, branched alkene, branched alkyne, cyclic alkene, or cyclic alkyne group.

7. The method of claim 1, wherein the one or more carbon-containing precursors comprise a branched alkane group or cyclic alkane group.

8. The method of claim 1, wherein the one or more carbon-containing precursors comprise a halo-substituted alkane, halo-substituted alkene, or halo-substituted alkyne group.

9. The method of claim 1, wherein the one or more carbon-containing precursors comprise a haloalkyl-substituted alkane, haloalkyl-substituted alkene, haloalkyl-substituted alkyne, carboxyl-substituted alkane, carboxyl-substituted alkene, carboxyl-substituted alkyne, cyano-substituted alkane, cyano-substituted alkene, cyano-substituted alkyne, carbonyl-substituted alkane, carbonyl-substituted alkene, carbonyl-substituted alkyne, sulfonyl-substituted alkane, sulfonyl-substituted alkene, sulfonyl-substituted alkyne, nitro-substituted alkane, nitro-substituted alkene, nitro-substituted alkyne, sulfonyl halide-substituted alkene, sulfonyl halide-substituted alkene, sulfonyl halide-substituted alkyne, sulfonamide-substituted alkane, sulfonamide-substituted alkene, or sulfonamide-substituted alkyne group.

10. The method of claim 1, wherein the one or more carbon-containing precursors comprise an alcohol-substituted alkane, alcohol-substituted alkene, alcohol-substituted alkyne, ether-substituted alkane, ether-substituted alkene, ether-substituted alkyne, ether-substituted alkane, ether-substituted alkene, ether-substituted alkyne, O-acyl-substituted alkane, O-acyl-substituted alkene, O-acyl-substituted alkyne, amine-substituted alkane, amine-substituted alkene, amine-substituted alkyne, N-acyl-substituted alkane, N-acyl-substituted alkene, or N-acyl-substituted alkyne group.

11. The method of claim 1, wherein the amorphous or crystalline carbon film is an amorphous carbon film having a hydrogen content between about 20 atomic % and about 70 atomic %.

12. The method of claim 11, wherein the substrate has one or more recessed features, the amorphous or crystalline carbon film being deposited in the one or more recessed features and having a step coverage equal to or greater than about 90%.

13. The method of claim 11, wherein the amorphous carbon film has a refractive index between about 1.5 and about 2.5 and a density between about 1.1 g/cm³ and about 3.5 g/cm³.

14. The method of claim 11, wherein the amorphous carbon film is deposited at a deposition rate equal to or greater than about 4 Å per minute at a deposition temperature between about 50° C. and about 550° C.

15. The method of claim 1, wherein an amount of sp3 carbon bonding in the amorphous or crystalline carbon film is equal to or greater than about 25%.

16. A method of depositing an amorphous hydrogenated carbon film on a substrate, the method comprising:
flowing one or more carbon-containing precursors into a reaction chamber toward a substrate in the reaction chamber, each of the carbon-containing precursors having at least one of: one or more C—C bonds or one or more C—H bonds;
generating, from a hydrogen source gas, radicals of hydrogen in a remote plasma source that is positioned upstream of the one or more carbon-containing precursors; and
introducing the radicals of hydrogen into the reaction chamber and toward the substrate, wherein the radicals are in an energy state sufficient to activate the one or more C—C bonds and/or the one or more C—H bonds and form activated carbon-containing precursors in an environment adjacent to the substrate, wherein the activated carbon-containing precursors deposit to form an amorphous hydrogenated carbon film on the substrate, a hydrogen content between about 20 atomic % and about 70 atomic %.

17. The method of claim 16, wherein the amorphous hydrogenated carbon film has a density between about 1.1 g/cm³ and about 3.5 g/cm³.

18. The method of claim 16, wherein the one or more carbon-containing precursors comprise at least one of a linear alkene, linear alkyne, branched alkene, branched alkyne, cyclic alkene group, or cyclic alkyne group.

19. The method of claim 16, wherein the one or more carbon-containing precursors comprise a branched alkane group and/or cyclic alkane group.

20. The method of claim 16, wherein the substrate has one or more recessed features, the amorphous hydrogenated carbon film being deposited in the one or more recessed features and having a step coverage equal to or greater than about 90%.
